(19) United States
(12) Patent Application Publication
(10) Pub. No.: US 2025/0159997 A1
(43) Pub. Date: May 15, 2025

(54) ENLARGED BOTTOM CONTACT AREA IN STACKED TRANSISTORS

(71) Applicant: INTERNATIONAL BUSINESS MACHINES CORPORATION, ARMONK, NY (US)

(72) Inventors: Brent A. Anderson, Jericho, VT (US); Jay William Strane, Wappingers Falls, NY (US); Ruilong Xie, Niskayuna, NY (US); Albert M. Chu, Nashua, NH (US); Junli Wang, Slingerlands, NY (US)

(21) Appl. No.: 18/509,382

(22) Filed: Nov. 15, 2023

(51) Int. Cl. H01L 27/12; H01L 21/822

(52) U.S. Cl. CPC H10D 87/00; H10D 84/038; H10D 88/01

(57) ABSTRACT

Embodiments of present invention provide a semiconductor structure. The semiconductor structure includes a first transistor on a substrate; a second transistor on top of the first transistor; and a source/drain (S/D) contact contacting a first S/D region of the first transistor, where the S/D contact has a horizontal portion and a vertical portion, the horizontal portion extending from a sidewall of the vertical portion and a portion of the horizontal portion being vertically between the first S/D region of the first transistor and a second S/D region of the second transistor. A method of forming the same is also provided.

### BACKGROUND

The present application relates to manufacturing of semiconductor integrated circuits. More particularly, it relates to method of forming a S/D contact with an enlarged contact area to a bottom transistor in a stacked transistor structure and the structure formed thereby.

As semiconductor industry moves towards manufacturing semiconductor integrated circuits or chips with smaller node, areas of semiconductor device for forming electric contact also shrink, which inevitably results in contacts with high resistance. For example, in a stacked transistor structure, because of the existence of a top transistor, access to a bottom transistor underneath the top transistor is partially blocked by the top transistor, resulting in an even smaller un-blocked contact areas to the bottom transistor.

### SUMMARY

Embodiments of present invention provide a semiconductor structure. The semiconductor structure includes a first transistor on a substrate; a second transistor on top of the first transistor; and a source/drain (S/D) contact contacting a first S/D region of the first transistor, where the S/D contact has a horizontal portion and a vertical portion, the horizontal portion extending from a sidewall of the vertical portion and a portion of the horizontal portion being vertically between the first S/D region of the first transistor and a second S/D region of the second transistor.

In one embodiment, a portion of the first S/D region of the first transistor is vertically outside the second S/D region of the second transistor.

In another embodiment, a bottom surface of the vertical portion of the S/D contact is in direct contact with the portion of the first S/D region of the first transistor and is below the horizontal portion of the S/D contact.

In yet another embodiment, a portion of the sidewall of the vertical portion of the S/D contact is in direct contact with the portion of the first S/D region of the first transistor and is below the horizontal portion of the S/D contact.

In one embodiment, the horizontal portion of the S/D contact is horizontally in contact with a dummy sheet, the dummy sheet being directly on top of the first S/D region of the first transistor.

In another embodiment, the horizontal portion of the S/D contact and the dummy sheet have a substantially same thickness and are substantially coplanar.

In yet another embodiment, the first transistor is a first nanosheet transistor having a first set of nanosheets of a first width, the second transistor is a second nanosheet transistor having a second set of nanosheets of a second width, and the second width is narrower than the first width.

Embodiments of present invention provide a method of forming a semiconductor structure. The method includes forming a first source/drain (S/D) region of a first transistor on a substrate; forming a sacrificial sheet directly on top of the first S/D region of the first transistor; forming a second S/D region of a second transistor, the second S/D region being on top of the first S/D region such that a portion of the first S/D region of the first transistor being vertically outside the second S/D region of the second transistor; depositing a dielectric layer covering the first and the second S/D region; creating a vertical opening in the dielectric layer, the vertical opening exposing the portion of the first S/D region; selectively removing at least a portion of the sacrificial sheet to create a horizontal opening directly above the first S/D region of the first transistor; and forming a S/D contact, the S/D contact having a horizontal portion in the horizontal opening and a vertical portion in the vertical opening.

In one embodiment, the vertical opening extends through the sacrificial sheet to expose a sidewall thereof.

In one embodiment, selectively removing the at least a portion of the sacrificial sheet comprises selectively etching the sacrificial sheet through the sidewall exposed by the vertical opening.

In another embodiment, selectively removing the at least a portion of the sacrificial sheet comprises selectively etching the sacrificial sheet to create the horizontal opening where at least a portion of the horizontal opening is vertically between the first S/D region of the first transistor and the second S/D region of the second transistor.

In one embodiment, selectively etching the sacrificial sheet causes a portion of the sacrificial sheet to remain above the first S/D region of the first transistor as a dummy sheet.

In another embodiment, selectively etching the sacrificial sheet causes the sacrificial sheet above the first S/D region of the first transistor being entirely removed.

In yet another embodiment, forming the S/D contact comprises depositing a conductive material in the horizontal opening and the vertical portion to form the horizontal portion and the vertical portion of the S/D contact.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, 1C, and 1D to FIGS. 19A, 19B, 19C, and 19D are demonstrative illustrations of cross-sectional views of a semiconductor structure in different steps of manufacturing thereof according to embodiments of present invention; and

FIG. 20 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

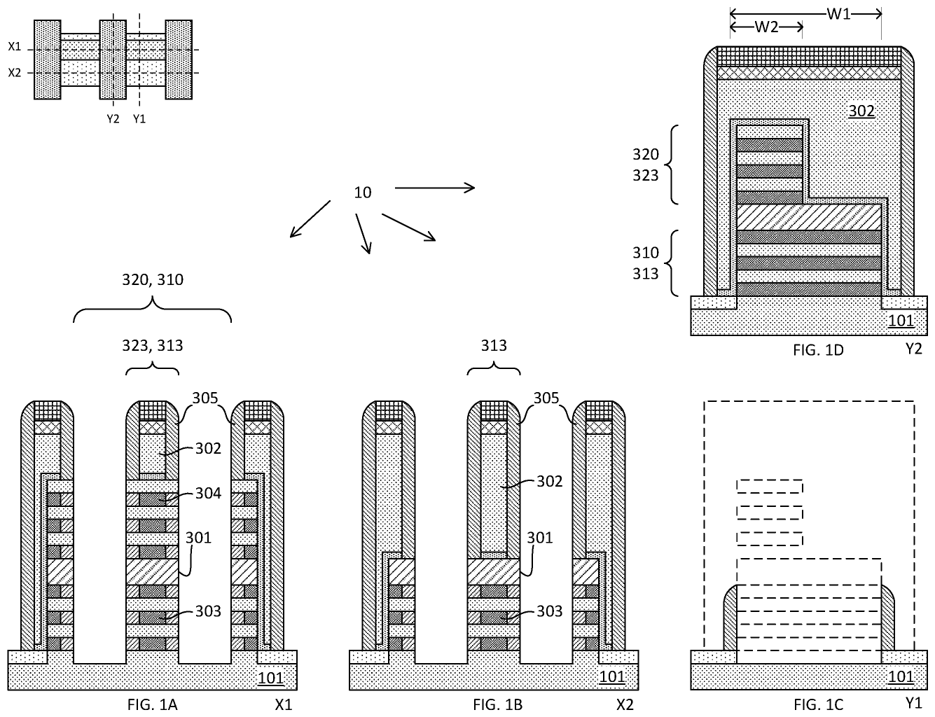

FIGS. 1A, 1B, 1C, and 1D are demonstrative illustrations of cross-sectional views of a semiconductor structure in a step of manufacturing thereof according to one embodiment of present invention. More specifically, as is illustrated in a simplified top view of the structure at the top-left corner of the drawing sheet, FIG. 1A is a cross-sectional view of the semiconductor structure along a dashed line X1 made across a stack of gates of a stack of transistors in a direction along the length of the gates. FIG. 1B is a cross-sectional view of the semiconductor structure along a dashed line X2 made across the gate of a bottom transistor of the stack of transistors. On the other hand, FIG. 1C is a cross-sectional view of the semiconductor structure along a dashed line Y1 made at a source/drain (S/D) region in a direction along the width of the gate. FIG. 1D is a cross-sectional view of the semiconductor structure along a dashed line Y2 made at the gate in a direction along the width of the gate.

As its purpose is to illustrate locations of various cross-sections shown in FIGS. 1A, 1B, 1C, and 1D, the simplified top view of the structure at the top-left corner of the drawing sheet may illustrate only selective elements such as, for example, nanosheets, gates, S/D regions, and/or other elements that may yet to be formed or whose views may be blocked. Elements such as dielectric cap layer, sidewall spacers, etc. may not be illustrated so as not to overcrowd the view, to the extent that their omission does not hinder description of embodiments of present invention, which are mainly provided hereinafter in conjunction with reference to FIGS. 1A, 1B, 1C, and 1D. It is also noted that dashed lines in the drawings, such as in FIG. 1C, may illustrate features that are either behind or in front of, but not directly at, the cross-section.

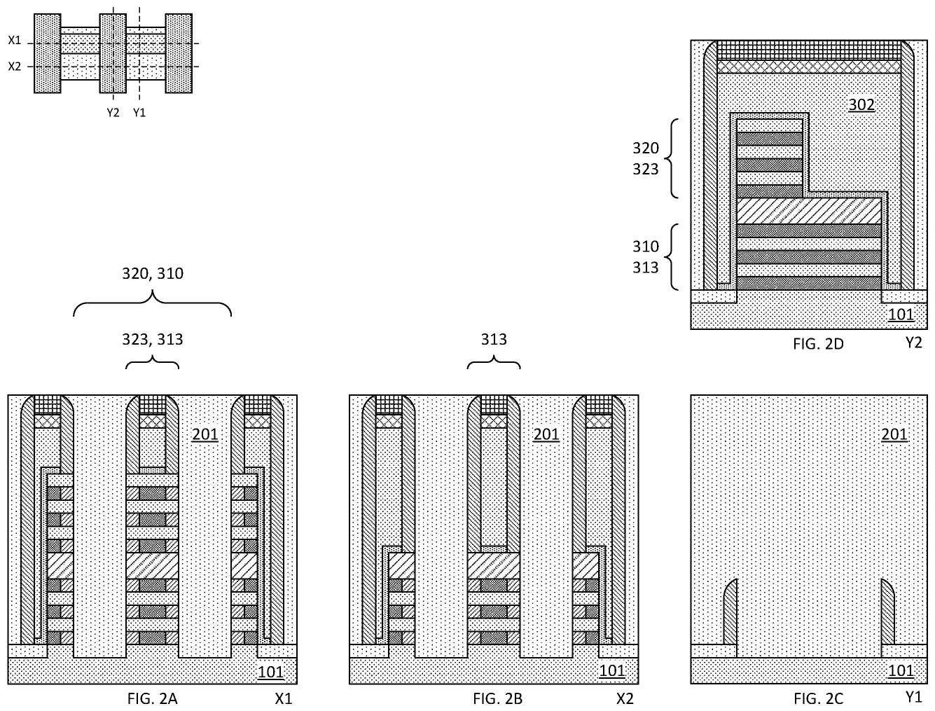

Likewise, FIGS. 2A, 2B, 2C, and 2D to FIGS. 19A, 19B, 19C, and 19D are demonstrative cross-sectional views of the semiconductor structure, at different manufacturing steps and/or stages, illustrated in manners similar to FIGS. 1A, 1B, 1C, and 1D respectively.

Embodiments of present invention provide receiving or providing a semiconductor structure 10 as is demonstratively illustrated in FIGS. 1A, 1B, 1C, and 1D. The semiconductor structure 10 includes a semiconductor substrate 101, a first transistor 310 on top of the semiconductor substrate 101, and a second transistor 320 on top of the first transistor 310. The semiconductor substrate 101 may be a bulk silicon (Si) substrate, a silicon-germanium (SiGe) substrate, a silicon-on-insulator (SOI) substrate, or any other suitable substrate. In one embodiment, the first and the second transistor 310 and 320 under manufacturing may be a first and a second nanosheet transistor and thus the first transistor 310 may include a first set of nanosheets of a first width W1 and the second transistor 320 may include a second set of nanosheets of a second width W2. The first width W1 may be wider than the second width W2. As is illustrated in FIG. 1D, the second set of nanosheets may be partially on top of the first set of nanosheets. In other words, a portion of the first set of nanosheets is vertically outside an area covered by the second set of nanosheets.

The semiconductor structure 10 may further include a stack of sacrificial gates. For example, it may include a first sacrificial gate 313 on top of the semiconductor substrate 101 and a second sacrificial gate 323 on top of the first sacrificial gate 313. The second sacrificial gate 323 may be separated and/or insulated from the first sacrificial gate 313 by a middle-dielectric-insulator (MDI) layer 301. The first and the second sacrificial gate 313 and 323 may later be transformed into metal gates, for example, in a replacement-metal-gate process.

The first sacrificial gate 313 may include the first set of nanosheets separated by a first set of sacrificial sheets 303. Similarly, the second sacrificial gate 323 may include the second set of nanosheets separated by a second set of sacrificial sheets 304. Inner spacers may be formed at the ends of the first and the second set of sacrificial sheets 303 and 304. In one embodiment, the first and second sets of nanosheets may be silicon (Si) nanosheets and the first and second sets of sacrificial sheets may be silicon-germanium (SiGe) sheets. A gate mask 302 of, for example, polysilicon (P—Si) may be formed on top of the stack of sacrificial gates and a set of sidewall spacers 305 of, for example, silicoboron-carbonitride (SiBCN) may be formed at the sidewalls of the gate mask 302. In one embodiment, the gate mask 302 may be covered by a hard mask which may include, for example, an oxide layer on top of a silicon-nitride (SiN) layer and together, the gate mask 302 and the hard mask on top thereof may collectively be referred to as a hard mask.

FIGS. 2A, 2B, 2C, and 2D are demonstrative illustrations of cross-sectional views of a semiconductor structure in a step of manufacturing thereof according to one embodiment of present invention. More specifically, following the step illustrated in FIGS. 1A, 1B, 1C, and 1D, embodiments of present invention provide forming a spin-on glass (SOG) layer 201 covering the semiconductor structure 10. More particularly, the SOG layer 201 may be formed to surround the stack of sacrificial gates 313/323 by filling trench openings or spaces between the stack of sacrificial gates 313/323 and nearby stacks of sacrificial gates or dummy gate structures. After forming the SOG layer 201, a chemical-mechanical-polishing (CMP) process may be applied to planarize a top surface of the SOG layer 201. In one embodiment, the top surface of the SOG layer 201 may be polished to expose or be made co-planar with a top surface of the hard mask layer that is on top of the gate mask 302.

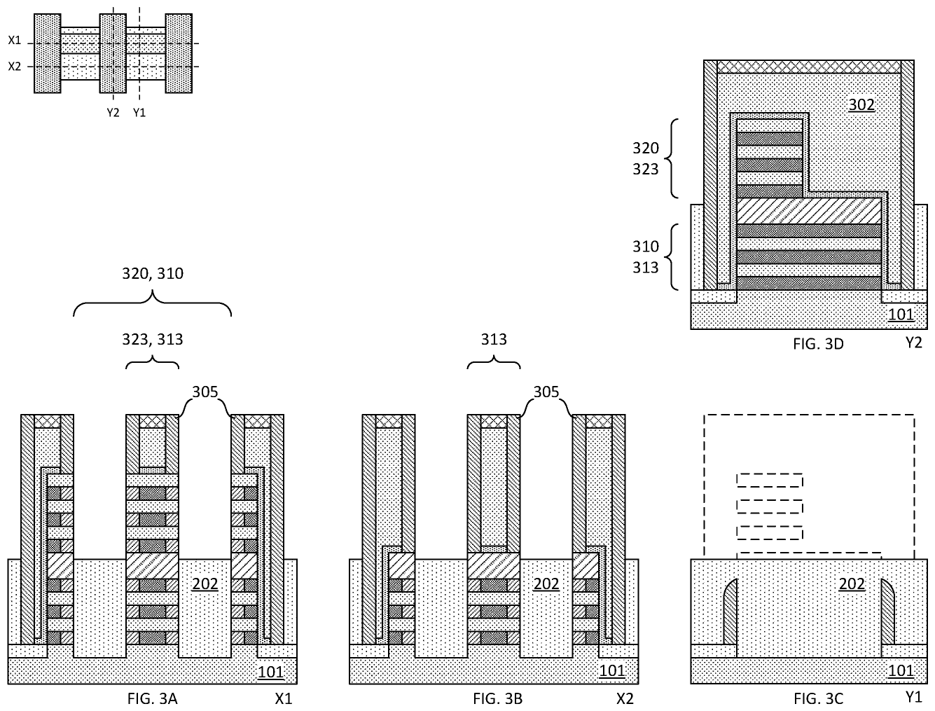

FIGS. 3A, 3B, 3C, and 3D are demonstrative illustrations of cross-sectional views of a semiconductor structure in a step of manufacturing thereof according to one embodiment of present invention. More specifically, following the step illustrated in FIGS. 2A, 2B, 2C, and 2D, embodiments of present invention provide further removing, in one embodiment, part of the hard mask layer such as the portion of oxide layer of the hard mask layer in a CMP process. Next, the SOG layer 201 between the stack of sacrificial gates and nearby stacks may be recessed through a selective etching process. The recessing transforms the SOG layer 201 into a SOG layer 202, which has a reduced height at or around the MDI layer 301. Sidewalls of the second sacrificial gate 323 may be exposed by the recessing of the SOG layer 201.

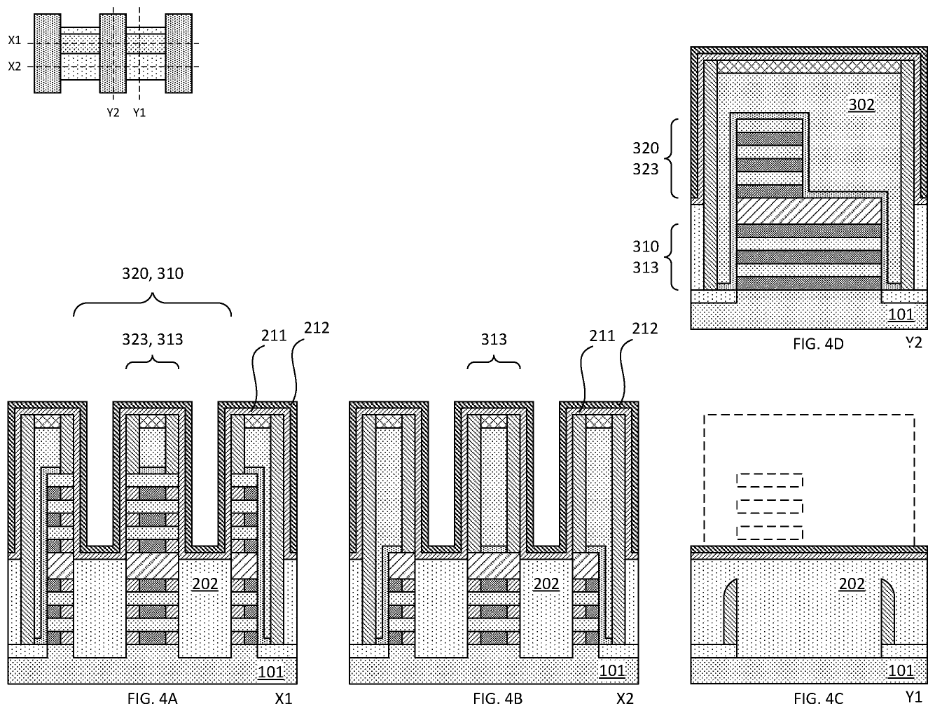

FIGS. 4A, 4B, 4C, and 4D are demonstrative illustrations of cross-sectional views of a semiconductor structure in a step of manufacturing thereof according to one embodiment of present invention. More specifically, following the step illustrated in FIGS. 3A, 3B, 3C, and 3D, embodiments of present invention provide covering the exposed sidewalls of the second sacrificial gate 323 with one or more dielectric liners. For example, a first dielectric liner 211 of, for example, oxide may be formed to cover the sidewalls of the second sacrificial gate 323 and a second dielectric liner 212 of, for example, SiN may be formed on top of the first dielectric liner 211. The dielectric liners are formed such that the first sacrificial gate 313 may next be processed while the second sacrificial gate 323 is being protected as being described below in more details.

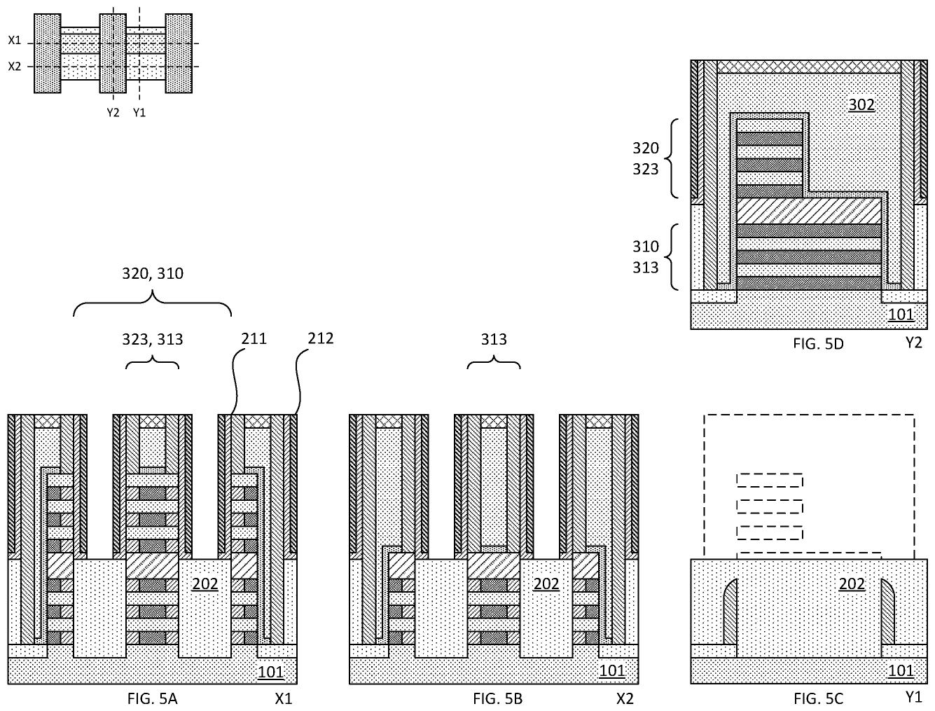

FIGS. 5A, 5B, 5C, and 5D are demonstrative illustrations of cross-sectional views of a semiconductor structure in a step of manufacturing thereof according to one embodiment of present invention. More specifically, following the step illustrated in FIGS. 4A, 4B, 4C, and 4D, embodiments of present invention provide applying a directional and/or selective etching process such as, for example, a reactive-ion-etching (RIE) process in removing horizontal portions of the first and second dielectric liners 211 and 212, leaving only vertical portions of the first and the second dielectric liners 211 and 212 protecting sidewalls of the second sacrificial gate 323. More particularly, the directional etching process removes portions of the first and second dielectric liners 211 and 212 that are on top of the SOG layer 202, subjecting the SOG layer 202 for further processing as being described below in more details.

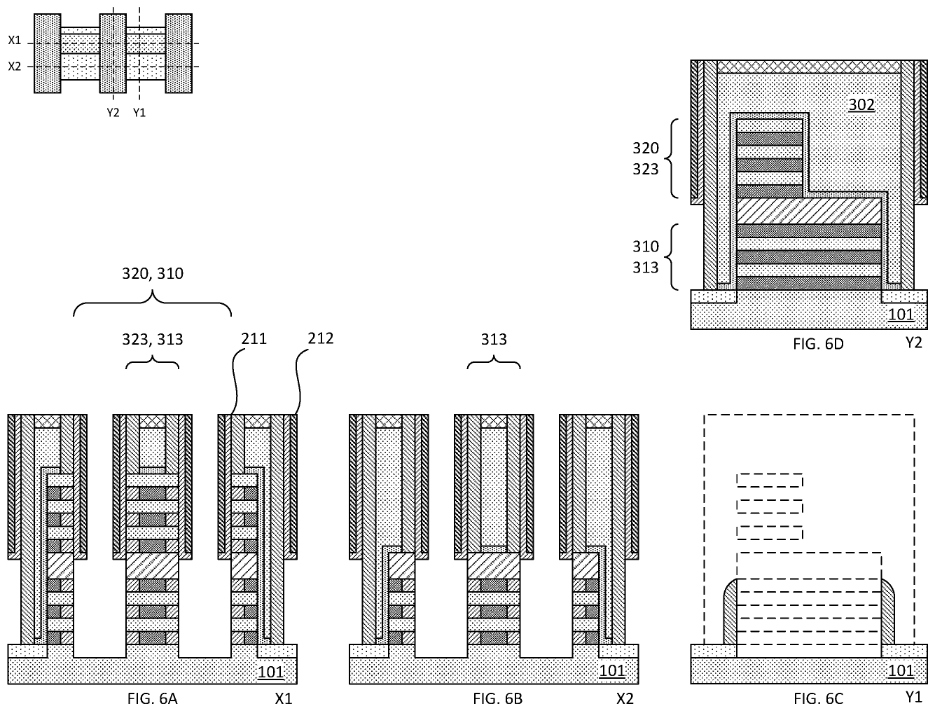

FIGS. 6A, 6B, 6C, and 6D are demonstrative illustrations of cross-sectional views of a semiconductor structure in a step of manufacturing thereof according to one embodiment of present invention. More specifically, following the step illustrated in FIGS. 5A, 5B, 5C, and 5D, embodiments of present invention provide stripping or removing the exposed SOG layer 202 thereby exposing the sidewalls of the first sacrificial gate 313 that were previously covered and/or protected by the SOG layer 202. A dry or wet cleaning process may then be applied to remove any residuals possibly at the sidewalls of the first sacrificial gate 313 in preparation for epitaxially forming source/drain regions in a next step.

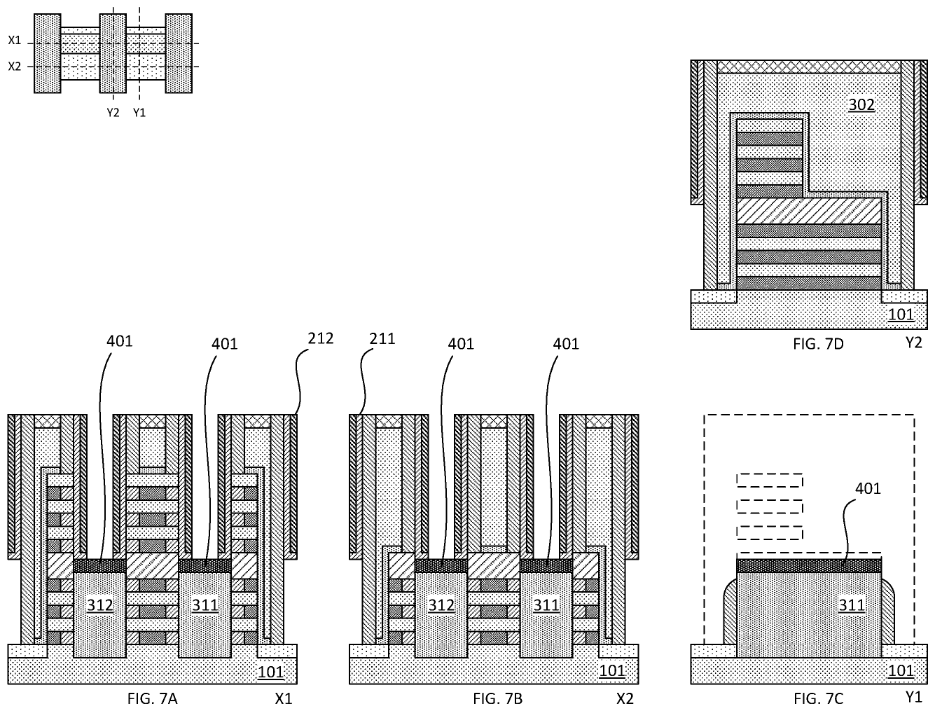

FIGS. 7A, 7B, 7C, and 7D are demonstrative illustrations of cross-sectional views of a semiconductor structure in a step of manufacturing thereof according to one embodiment of present invention. More specifically, following the step illustrated in FIGS. 6A, 6B, 6C, and 6D, embodiments of present invention provide forming source/drain (S/D) regions, such as a first S/D region 311 and a third S/D region 312 of the first transistor 310 of the semiconductor structure 10, at sidewalls of the first sacrificial gate 313. The first and the third S/D region 311 and 312 may be formed through epitaxially growing silicon-phosphorus (SiP) from the first set of Si nanosheets of the first sacrificial gate 313 while the second set of Si nanosheets of the second sacrificial gate 323 are covered and thus protected by the first and the second dielectric liners 211 and 212. The first transistor 310 may be an n-type FET such as an n-type nanosheet transistor.

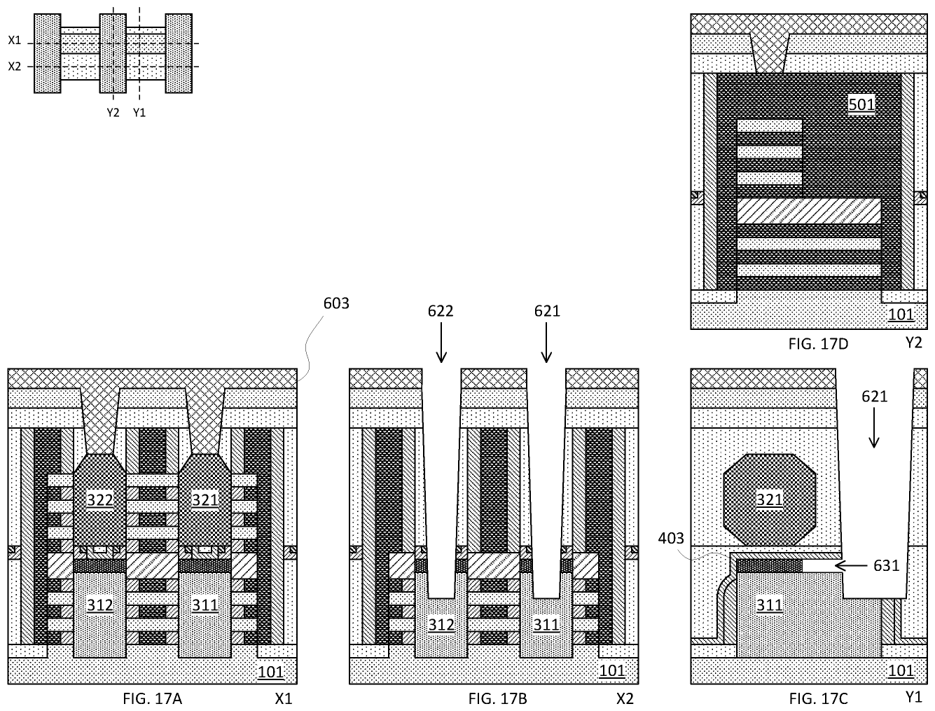

Following the formation of the first and the third S/D region 311 and 312, a sacrificial sheet 401 may be formed on top of the first and the third S/D region 311 and 312. In one embodiment, the sacrificial sheet 401 may be a layer of SiGe that may be formed through a selective growth process such as, for example, a selective epitaxial growth process. The sacrificial sheet 401 provides etch selectivity with respect to the underneath first and third S/D regions 311 and 312 of SiP, and with respect to the dielectric material to be formed on top of the sacrificial sheet 401 such as SiN or silicon-oxide (SiO₂). As will be described below in more details with reference to FIGS. 17-19, part of the sacrificial sheet 401 may be removed and replaced later in a process of forming an enlarged S/D contact area of the first transistor 310.

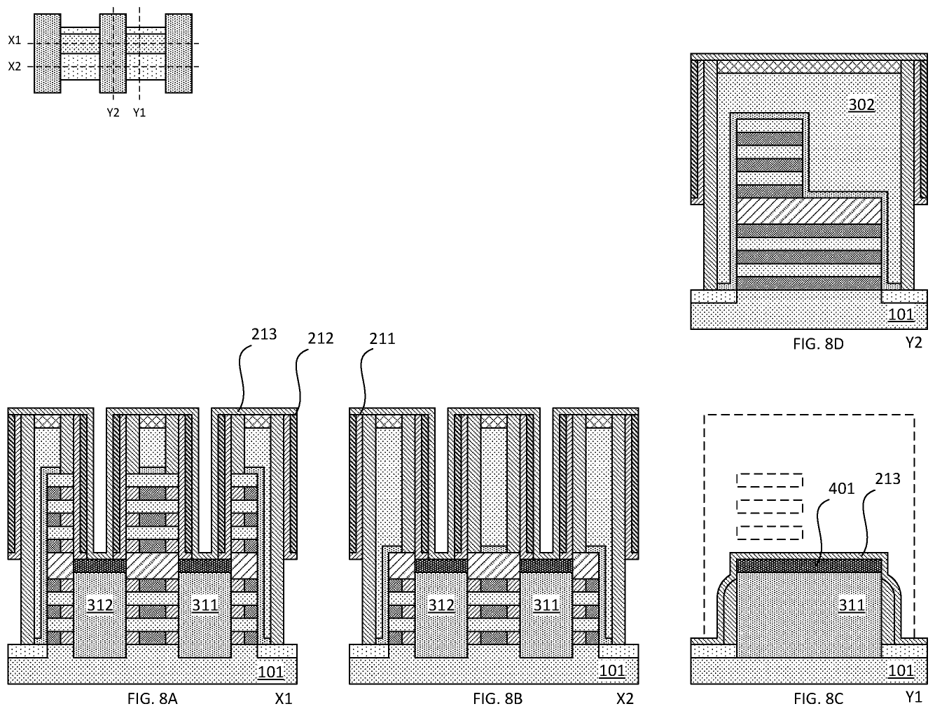

FIGS. 8A, 8B, 8C, and 8D are demonstrative illustrations of cross-sectional views of a semiconductor structure in a step of manufacturing thereof according to one embodiment of present invention. More specifically, following the step illustrated in FIGS. 7A, 7B, 7C, and 7D, embodiments of present invention provide forming a third dielectric liner 213, such as a SiN liner, covering the top surface of the sacrificial sheet 401. The dielectric liner 213 may be formed on top of the gate mask 302 and next to the vertical portion of the second dielectric liner 212 thereby providing protection of the semiconductor structure 10 during subsequent processing steps such as, for example, in a process of densifying dielectric materials formed through a flowable chemical-vapor-deposition (FCVD) process.

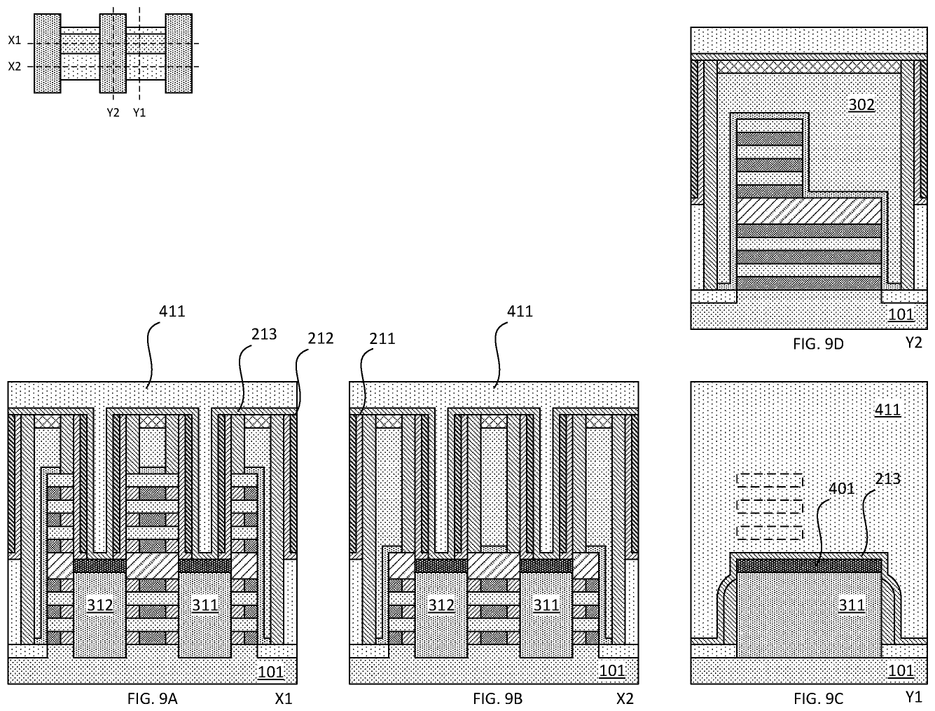

FIGS. 9A, 9B, 9C, and 9D are demonstrative illustrations of cross-sectional views of a semiconductor structure in a step of manufacturing thereof according to one embodiment of present invention. More specifically, following the step illustrated in FIGS. 8A, 8B, 8C, and 8D, embodiments of present invention provide filling the spaces or trench openings between the second sacrificial gate 323 and nearby sacrificial gates and/or structures and on top thereof with a dielectric material such as SiO₂ to form a dielectric layer 411. The dielectric layer 411 may be formed through, for example, a FCVD process which may be suitable for filling trenches and/or openings of high aspect ratio. However, embodiments of present invention are not limited in this aspect and other processes such as, for example, a chemical-vapor-deposition (CVD) process, a physical-vapor-deposition (PVD) process, an atomic-layer-deposition (ALD) process, or any other currently existing or future developed processes may be used as well. A top surface of the dielectric layer 411 may be planarized through a CMP process.

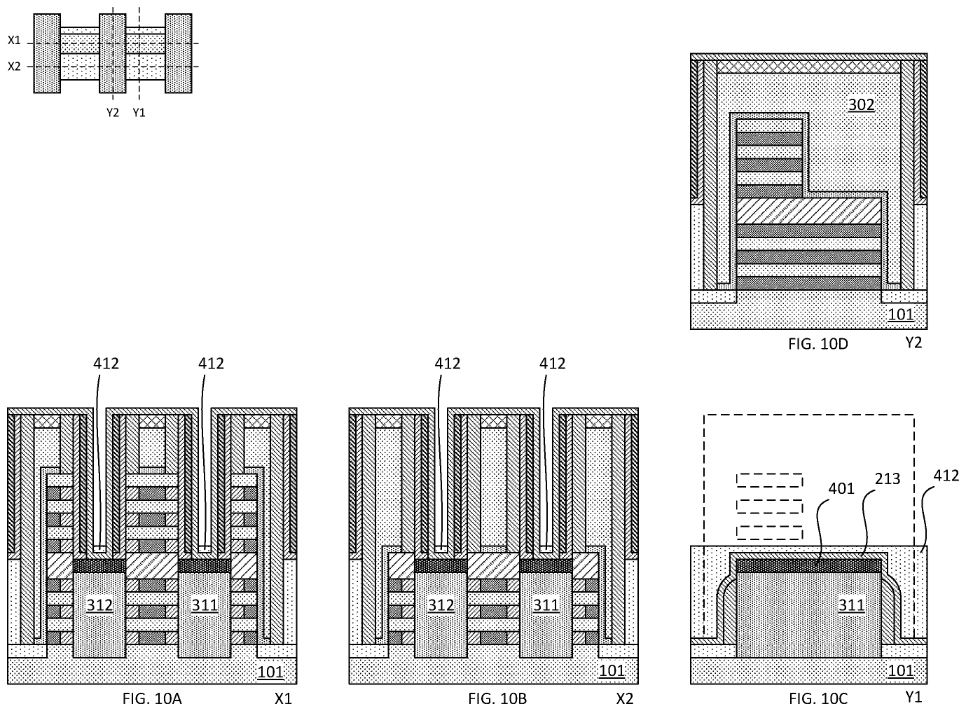

FIGS. 10A, 10B, 10C, and 10D are demonstrative illustrations of cross-sectional views of a semiconductor structure in a step of manufacturing thereof according to one embodiment of present invention. More specifically, following the step illustrated in FIGS. 9A, 9B, 9C, and 9D, embodiments of present invention provide recessing the dielectric layer 411 above the gate mask 302 and in-between the gaps or spaces between the second sacrificial gate 323 and nearby sacrificial gates and/or structure, through for example a wet or dry etch process, thereby forming a dielectric layer 412. The dielectric layer 412 formed thereby may continue to cover the sacrificial sheet 401 but may have a top surface that is below the second set of Si nanosheets of the second sacrificial gate 323. The dielectric layer 412 may work as a bottom spacer layer and, together with the third dielectric liner 213, may separate and/or insulate a second S/D region and a fourth S/D region of the second transistor 320 (to be formed later) from the sacrificial sheet 401, which may be transformed into a portion of an enlarged S/D contact for the first transistor 310 later.

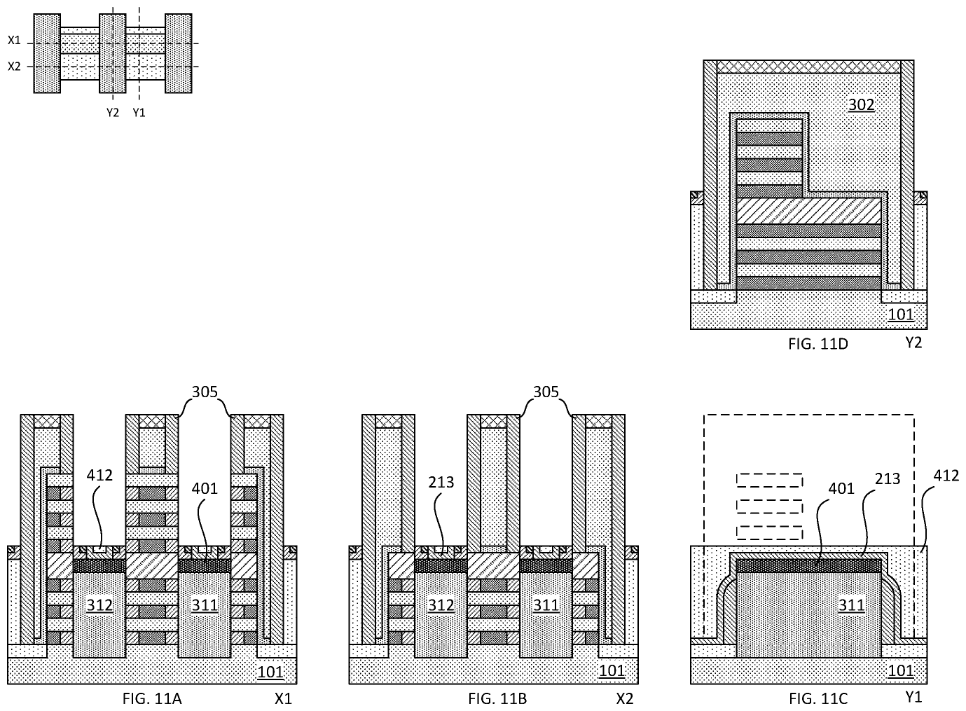

FIGS. 11A, 11B, 11C, and 11D are demonstrative illustrations of cross-sectional views of a semiconductor structure in a step of manufacturing thereof according to one embodiment of present invention. More specifically, following the step illustrated in FIGS. 10A, 10B, 10C, and 10D, embodiments of present invention provide selectively removing the third dielectric liner 213 that are not covered by the dielectric layer 412, and selectively removing the vertical portions of the second dielectric liner 212 and the first dielectric liner 211. The removal of the first, the second, and the third dielectric liner 211, 212, and 213 exposes sidewalls, particularly sidewalls of the second set of Si nanosheets of the second sacrificial gate 323 for further processing including forming S/D regions. The sidewalls of the second set of Si nanosheets may be optionally cleaned for epitaxially growing S/D regions later.

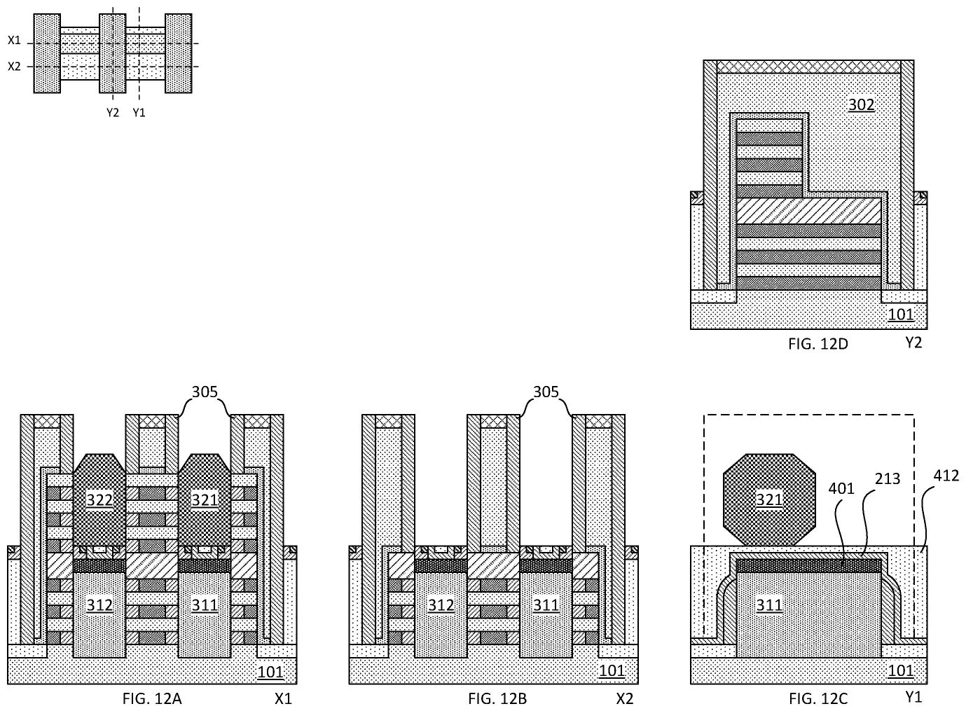

FIGS. 12A, 12B, 12C, and 12D are demonstrative illustrations of cross-sectional views of a semiconductor structure in a step of manufacturing thereof according to one embodiment of present invention. More specifically, following the step illustrated in FIGS. 11A, 11B, 11C, and 11D, embodiments of present invention provide forming S/D regions, such as a second S/D region 321 and a fourth S/D region 322 of the second transistor 320 of the semiconductor structure 10, at sidewalls of the second sacrificial gate 323. The second and the fourth S/D region 321 and 322 may be formed through epitaxially growing SiGe from sidewalls of the second set of Si nanosheets and the SiGe may contain a germanium (Ge) content level of about 25 at. % and thus may be referred to as a SiGe25. The second and the fourth S/D region 321 and 322 of SiGe25 may have a lower Ge content than Ge content level contained in the first set of sacrificial sheets 303 and the second set of sacrificial sheets 304. The first and the second set of sacrificial sheets 303 and 304 may typically contains a Ge content level of about 55 at. % which enables them to be selectively removed later in a replacement-metal-gate (RMG) process. The second transistor 320 may be a p-type FET such as a p-type nanosheet transistor.

It is to be noted here that in the above description, the first transistor 310 is a n-type FET and the second transistor 320 is a p-type FET, embodiments of present invention are not limited in this aspect. By using different materials such as, for example, using SiGe for the first and the third S/D region 311 and 312 of the first transistor 310 and using SiP for the third and the fourth S/D region 321 and 322 of the second transistor 320, the first transistor 310 may be formed as a p-type FET and the second transistor 320 may be formed as an n-type FET. In further embodiments, both the first and the second transistor 310 and 320 may be made as p-type transistors or n-type transistors.

In one embodiment, the second S/D region 321 of the second transistor 320 may have a horizontal width that is narrower than a horizontal width of the first S/D region 311 of the first transistor 310. This is because the second set of Si nanosheets of the second transistor 320 has a width W2 that is narrower than a width W1 of the first set of Si nanosheets of the first transistor 310. The second S/D region 321 may be on top of or over part of the first S/D region 311. In other words, a portion of the first S/D region 311 may be outside an area covered by the second S/D region 321.

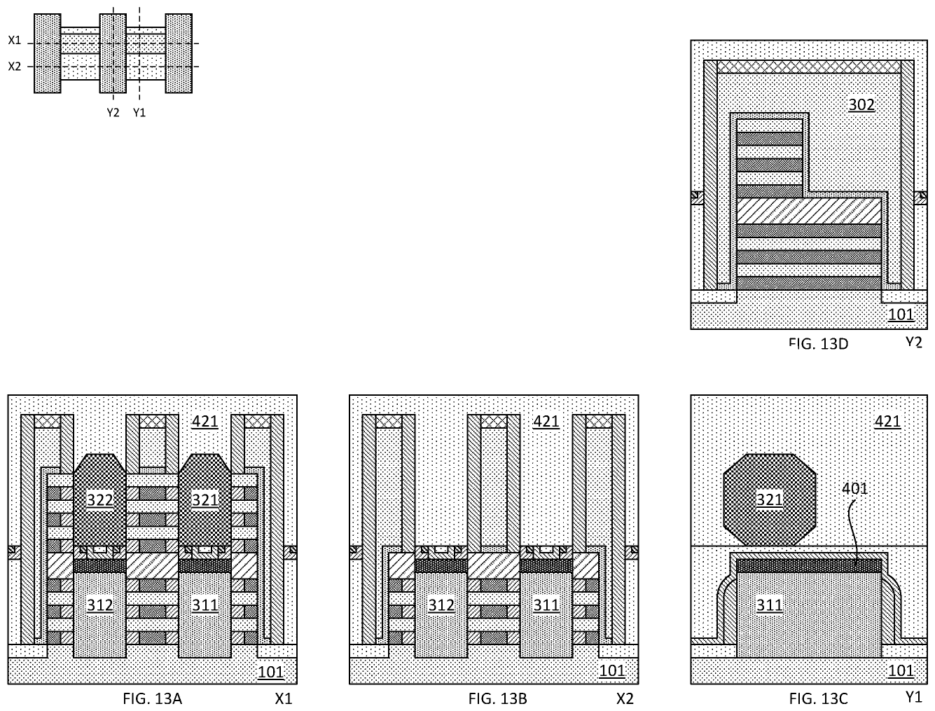

FIGS. 13A, 13B, 13C, and 13D are demonstrative illustrations of cross-sectional views of a semiconductor structure in a step of manufacturing thereof according to one embodiment of present invention. More specifically, following the step illustrated in FIGS. 12A, 12B, 12C, and 12D, embodiments of present invention provide forming a dielectric layer 421 on top of the second and the fourth S/D region 321 and 322. The dielectric layer 421 may be formed through, for example, a flowable CVD (FCVD) process or an ALD process to ensure that no vertical voids may be formed in the gaps or spaces between the second sacrificial gate 323 and nearby sacrificial gates and/or structures.

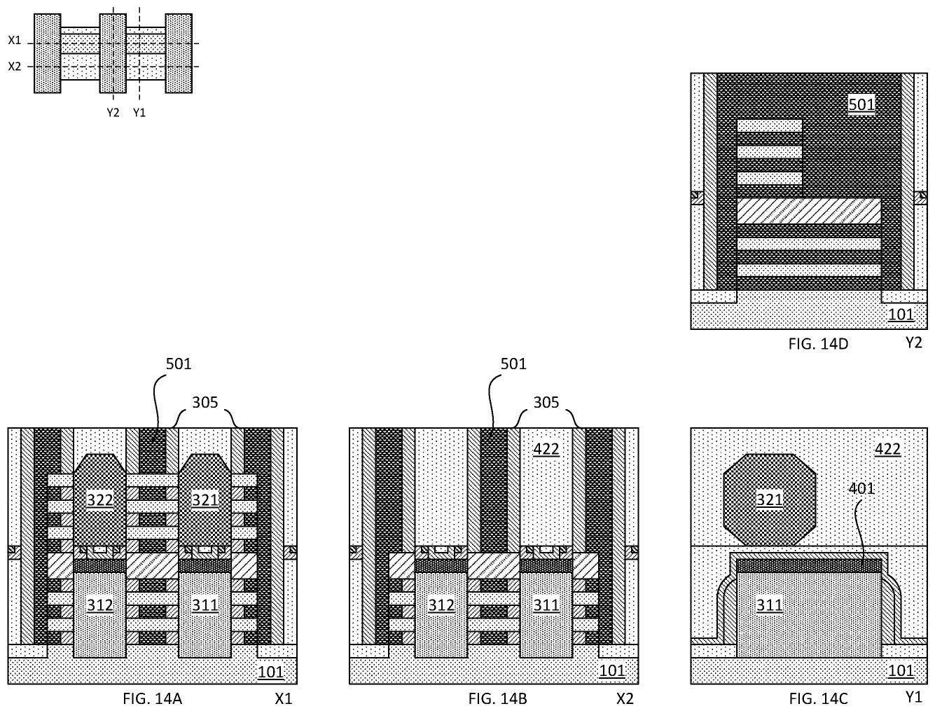

FIGS. 14A, 14B, 14C, and 14D are demonstrative illustrations of cross-sectional views of a semiconductor structure in a step of manufacturing thereof according to one embodiment of present invention. More specifically, following the step illustrated in FIGS. 13A, 13B, 13C, and 13D, embodiments of present invention provide planarizing the dielectric layer 421 and removing any remaining hard mask, for example through a CMP process, to expose the gate mask 302 thereby forming a dielectric layer 422. Subsequently, a replacement-metal-gate (RMG) process may be applied to remove and replace the first and the second set of sacrificial sheets 303 and 304 with a metal gate 501. For example, the first and the second set of sacrificial sheets 303 and 304 may first be removed to create openings surrounding the first and the second set of Si nanosheets. A gate dielectric layer may be deposited to cover the exposed first and second set of Si nanosheets. One or more work-function metals may be deposited on top of the gate dielectric layer, and finally one or more layers of conductive material may be formed on top of the one or more work-function metal to form the metal gate 501. A CMP process may be applied to planarize a top surface of the metal gate 501.

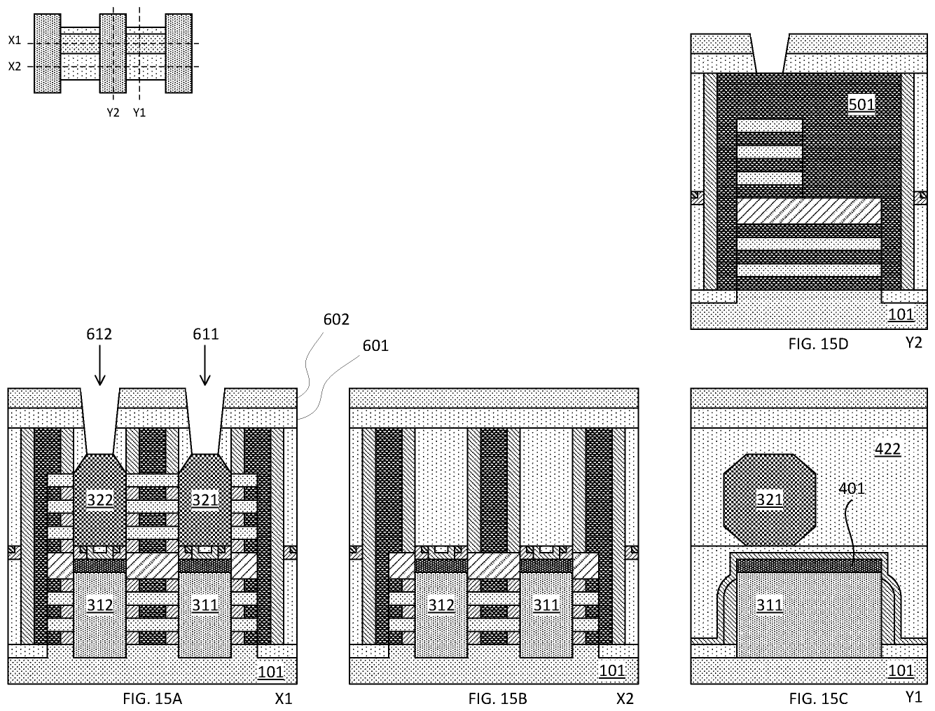

FIGS. 15A, 15B, 15C, and 15D are demonstrative illustrations of cross-sectional views of a semiconductor structure in a step of manufacturing thereof according to one embodiment of present invention. More specifically, following the step illustrated in FIGS. 14A, 14B, 14C, and 14D, embodiments of present invention provide forming a dielectric layer 601 on top of the metal gate 501 and the dielectric layer 422. Next, a hard mask layer 602 may be formed on top of the dielectric layer 601. Contact openings, such as a first and a second contact opening 611 and 612 of the second transistor 320, may be created in the hard mask layer 602 and in the dielectric layers 601 and 422 to expose top surfaces of, for example, the second S/D region 321 and the fourth S/D region 322. Gate contact opening may also be created to expose the metal gate 501 as is illustrated in FIG. 15D.

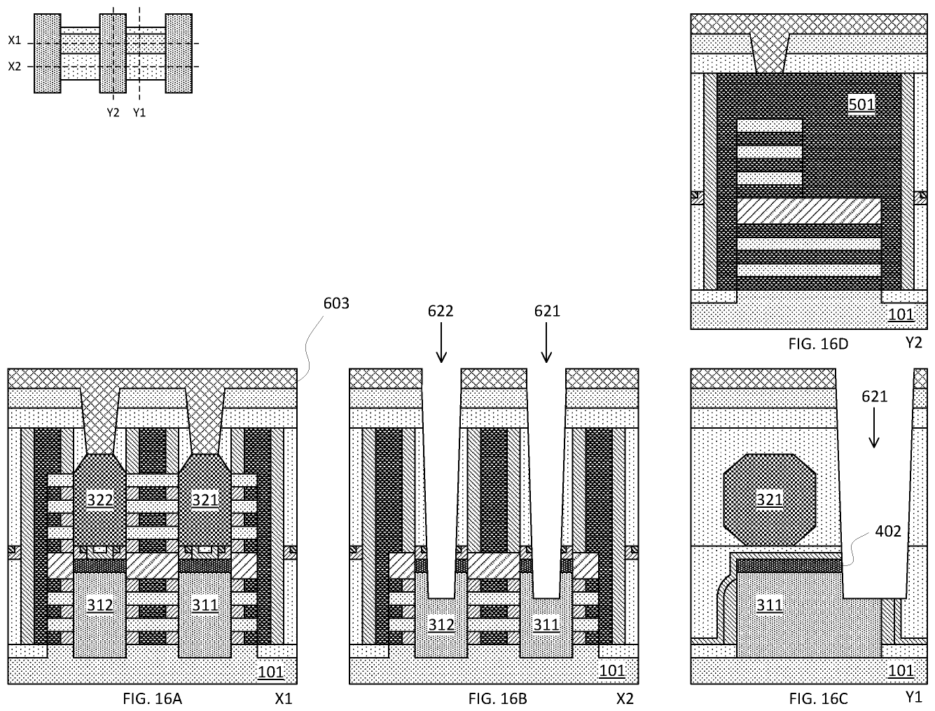

FIGS. 16A, 16B, 16C, and 16D are demonstrative illustrations of cross-sectional views of a semiconductor structure in a step of manufacturing thereof according to one embodiment of present invention. More specifically, following the step illustrated in FIGS. 15A, 15B, 15C, and 15D, embodiments of present invention provide forming another hard mask layer 603 covering a top surface of the semiconductor structure 10. The hard mask layer 603 may also fill the first and the second contact opening 611 and 612 of the second transistor 320, thereby providing protection of the first and the second contact opening 611 and 612 in subsequent patterning processes. For example, a third and a fourth contact opening 621 and 622 may be created in the hard mask layer 603, which may subsequently be transferred onto the dielectric layers 601 and 422 to expose a portion of the sacrificial sheet 401. In exposing the sacrificial sheet 401, the third contact opening 621 may extend through the dielectric layer 412 and the third dielectric liner 213 underneath thereof and transform the sacrificial sheet 401 into a sacrificial sheet 402 with a sidewall thereof being exposed by the third contact opening 621. The third contact opening 621 may be partially etched into the first S/D region 311 to have a bottom surface that is below the sacrificial sheet 402.

FIGS. 17A, 17B, 17C, and 17D are demonstrative illustrations of cross-sectional views of a semiconductor structure in a step of manufacturing thereof according to one embodiment of present invention. More specifically, following the step illustrated in FIGS. 16A, 16B, 16C, and 16D, embodiments of present invention provide selectively etching the sacrificial sheet 402, through the third contact opening 621, to remove at least a portion of the sacrificial sheet 402 thereby forming a horizontal opening 631. The horizontal opening 631 is next to a remaining portion of the sacrificial sheet 402 which forms a dummy sheet 403. In one embodiment, the horizontal opening 631 has at least a portion thereof that is vertically between the second S/D region 321 and the first S/D region 311. In other words, at least a portion of the horizontal opening 631 is vertically underneath the second S/D region 321. In another embodiment, the selective etching process may remove the entire sacrificial sheet 402. In other words, the length of the horizontal opening 631 may be adjusted based upon design of the semiconductor structure 10 and needs for forming a horizontal portion of a S/D contact for the first transistor 310.

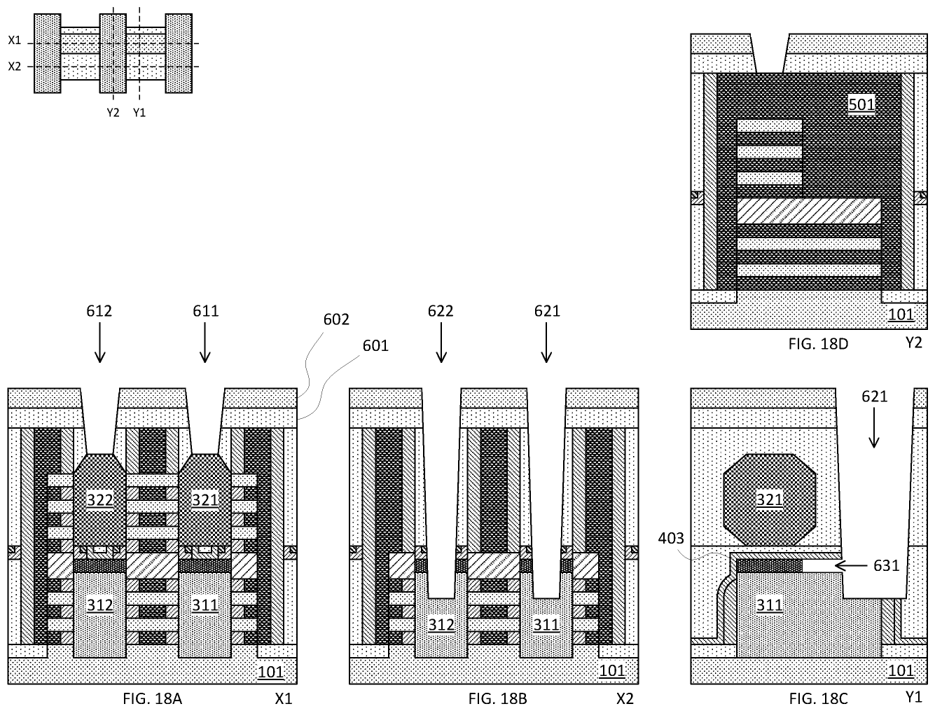

FIGS. 18A, 18B, 18C, and 18D are demonstrative illustrations of cross-sectional views of a semiconductor structure in a step of manufacturing thereof according to one embodiment of present invention. More specifically, following the step illustrated in FIGS. 17A, 17B, 17C, and 17D, embodiments of present invention provide selectively removing the hard mask layer 603, such as through a reactive-ion-etch (RIE) or selective wet strip process, to re-create the first and the second contact opening 611 and 612. The recreation of the first and the second contact opening 611 and 612 exposes top surfaces of the second and the fourth S/D regions 321 and 322 forming S/D contacts.

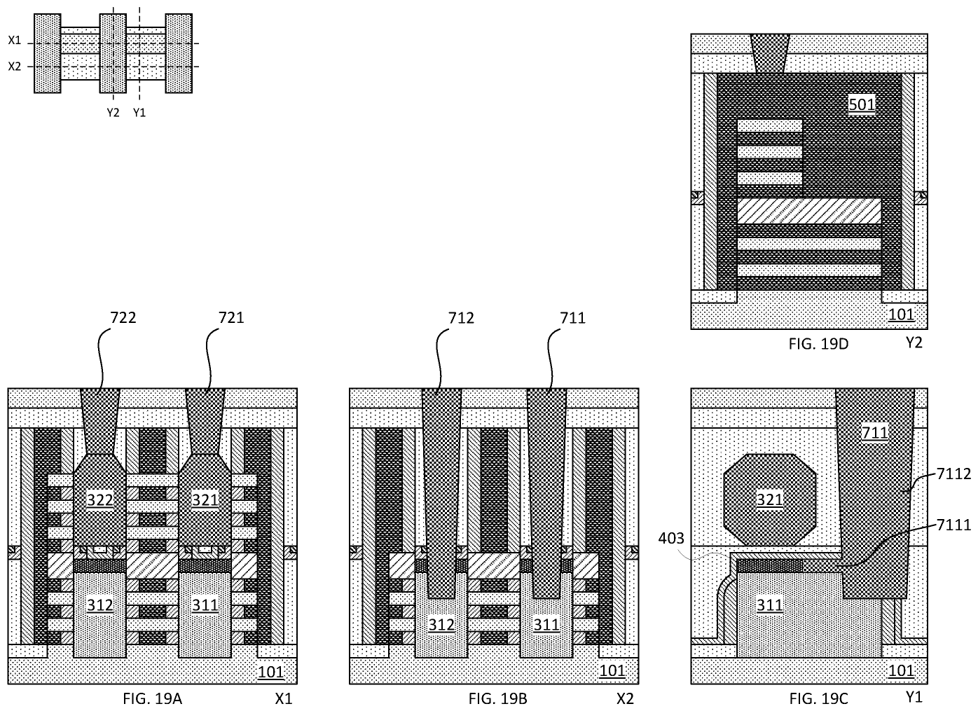

FIGS. 19A, 19B, 19C, and 19D are demonstrative illustrations of cross-sectional views of a semiconductor structure in a step of manufacturing thereof according to one embodiment of present invention. More specifically, following the step illustrated in FIGS. 18A, 18B, 18C, and 18D, embodiments of present invention provide filling the contact openings with a conductive material to form S/D contacts and/or gate contact. For example, a first and a second S/D contact 711 and 712 may be formed to contact the first and the third S/D region 311 and 312 of the first transistor 310, and a third and a fourth S/D contact 721 and 722 may be formed to contact the second and the fourth S/D region 321 and 322 of the second transistor 320.

In one embodiment, the first S/D contact 711 may have a horizontal portion 7111 and a vertical portion 7112 and the horizontal portion 7111 may extend from a sidewall surface of the vertical portion 7112. The vertical portion 7112 of the first S/D contact 711 may have a portion below a level of the horizontal portion 7111 to have a bottom surface that is below the horizontal portion 7111. The vertical portion 7112 may be in direct contact with a portion of the first S/D region 311 that is outside an area directly underneath the second S/D region 321.

On the other hand, and according to one embodiment, the horizontal portion 7111 of the first S/D contact 711 may have a portion vertically between the second S/D region 321 and the first S/D region 311. The horizontal portion 7111 may be horizontally in contact with a dummy sheet 403; may have a substantially same thickness as the dummy sheet 403; and may be substantially coplanar with the dummy sheet 403. The dummy sheet 403 may be directly on top of the first S/D region 311.

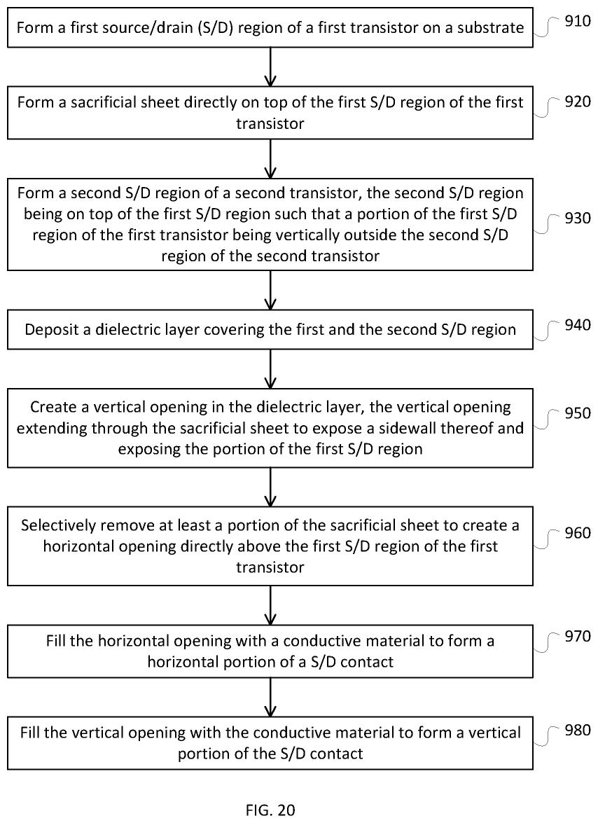

FIG. 20 is a demonstrative illustration of a flow-chart of a method of manufacturing a semiconductor structure according to embodiments of present invention. The method includes (910) forming a first source/drain (S/D) region of a first transistor on a substrate; (920) forming a sacrificial sheet directly on top of the first S/D region of the first transistor; (930) forming a second S/D region of a second transistor, the second S/D region being on top of the first S/D region such that a portion of the first S/D region of the first transistor being vertically outside the second S/D region of the second transistor; (940) depositing a dielectric layer covering the first and the second S/D region; (950) creating a vertical opening in the dielectric layer, the vertical opening extending through the sacrificial sheet to expose a sidewall thereof and exposing the portion of the first S/D region; (960) selectively removing at least a portion of the sacrificial sheet to create a horizontal opening directly above the first S/D region of the first transistor; (970) filling the horizontal opening with a conductive material to form a horizontal portion of a S/D contact; and (980) filling the vertical opening with the conductive material to form a vertical portion of the S/D contact.

Various examples may possibly be described by one or more of the following features in the following numbered clauses:

Clause 1: A semiconductor structure comprising a first transistor on a substrate; a second transistor on top of the first transistor; and a source/drain (S/D) contact contacting a first S/D region of the first transistor, wherein the S/D contact has a horizontal portion and a vertical portion, the horizontal portion extending from a sidewall of the vertical portion and a portion of the horizontal portion being vertically between the first S/D region of the first transistor and a second S/D region of the second transistor.

Clause 2: The semiconductor structure of clause 1, wherein a portion of the first S/D region of the first transistor is vertically outside the second S/D region of the second transistor.

Clause 3: The semiconductor structure of clause 2, wherein a bottom surface of the vertical portion of the S/D contact is in direct contact with the portion of the first S/D region of the first transistor and is below the horizontal portion of the S/D contact.

Clause 4: The semiconductor structure of clause 2, wherein a portion of the sidewall of the vertical portion of the S/D contact is in direct contact with the portion of the first S/D region of the first transistor and is below the horizontal portion of the S/D contact.

Clause 5: The semiconductor structure of clause 1, wherein the horizontal portion of the S/D contact is horizontally in contact with a dummy sheet, the dummy sheet being directly on top of the first S/D region of the first transistor.

Clause 6: The semiconductor structure of clause 5, wherein the horizontal portion of the S/D contact and the dummy sheet have a substantially same thickness and are substantially coplanar.

Clause 7: The semiconductor structure of clause 1, wherein the first transistor is a first nanosheet transistor having a first set of nanosheets of a first width, the second transistor is a second nanosheet transistor having a second set of nanosheets of a second width, and the second width is narrower than the first width.

Clause 8: A method of forming a semiconductor structure comprising forming a first source/drain (S/D) region of a first transistor on a substrate; forming a sacrificial sheet directly on top of the first S/D region of the first transistor; forming a second S/D region of a second transistor, the second S/D region being on top of the first S/D region such that a portion of the first S/D region of the first transistor being vertically outside the second S/D region of the second transistor; depositing a dielectric layer covering the first and the second S/D region; creating a vertical opening in the dielectric layer, the vertical opening exposing the portion of the first S/D region; selectively removing at least a portion of the sacrificial sheet to create a horizontal opening directly above the first S/D region of the first transistor; and forming a S/D contact, the S/D contact having a horizontal portion in the horizontal opening and a vertical portion in the vertical opening.

Clause 9: The method of clause 8, wherein the vertical opening extends through the sacrificial sheet to expose a sidewall thereof.

Clause 10: The method of clause 9, wherein selectively removing the at least a portion of the sacrificial sheet comprises selectively etching the sacrificial sheet through the sidewall exposed by the vertical opening.

Clause 11: The method of clause 9, wherein selectively removing the at least a portion of the sacrificial sheet comprises selectively etching the sacrificial sheet to create the horizontal opening where at least a portion of the horizontal opening is vertically between the first S/D region of the first transistor and the second S/D region of the second transistor.

Clause 12: The method of clause 11, wherein selectively etching the sacrificial sheet causes a portion of the sacrificial sheet to remain above the first S/D region of the first transistor as a dummy sheet.

Clause 13: The method of clause 11, wherein selectively etching the sacrificial sheet causes the sacrificial sheet above the first S/D region of the first transistor being entirely removed.

Clause 14: The method of clause 8, wherein forming the S/D contact comprises depositing a conductive material in the horizontal opening and the vertical portion to form the horizontal portion and the vertical portion of the S/D contact.

Clause 15: A semiconductor structure comprising a first nanosheet transistor on a substrate; a second nanosheet transistor on top of the first nanosheet transistor; and a source/drain (S/D) contact contacting a first S/D region of the first nanosheet transistor, wherein the S/D contact has a horizontal portion and a vertical portion, the horizontal portion extending from a sidewall of the vertical portion and covering a top surface of the first S/D region of the first nanosheet transistor.

Clause 16: The semiconductor structure of clause 15, wherein the first nanosheet transistor has a first set of nanosheets of a first width and the second nanosheet transistor has a second set of nanosheets of a second width with the second width being narrower than the first width, and wherein and a portion of the first S/D region of the first nanosheet transistor is vertically outside the second S/D region of the second nanosheet transistor.

Clause 17: The semiconductor structure of clause 16, wherein a bottom surface of the vertical portion of the S/D contact is in direct contact with the portion of the first S/D region of the first nanosheet transistor and is below the horizontal portion of the S/D contact.

Clause 18: The semiconductor structure of clause 16, wherein a portion of the sidewall of the vertical portion of the S/D contact is in direct contact with the portion of the first S/D region of the first nanosheet transistor and is below the horizontal portion of the S/D contact.

Clause 19: The semiconductor structure of clause 15, wherein at least a portion of the horizontal portion of the S/D contact is vertically between the first S/D region of the first nanosheet transistor and the second S/D region of the second nanosheet transistor, and the horizontal portion of the S/D contact is horizontally in contact with a dummy sheet, the dummy sheet being directly on top of the first S/D region of the first nanosheet transistor.

Clause 20: The semiconductor structure of clause 19, wherein the horizontal portion of the S/D contact and the dummy sheet have a substantially same thickness and are substantially coplanar.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first transistor on a substrate;
a second transistor on top of the first transistor; and
a source/drain (S/D) contact contacting a first S/D region of the first transistor,
wherein the S/D contact has a horizontal portion and a vertical portion, the horizontal portion extending from a sidewall of the vertical portion and a portion of the horizontal portion being vertically between the first S/D region of the first transistor and a second S/D region of the second transistor.

2. The semiconductor structure of claim 1, wherein a portion of the first S/D region of the first transistor is vertically outside the second S/D region of the second transistor.

3. The semiconductor structure of claim 2, wherein a bottom surface of the vertical portion of the S/D contact is in direct contact with the portion of the first S/D region of the first transistor and is below the horizontal portion of the S/D contact.

4. The semiconductor structure of claim 2, wherein a portion of the sidewall of the vertical portion of the S/D contact is in direct contact with the portion of the first S/D region of the first transistor and is below the horizontal portion of the S/D contact.

5. The semiconductor structure of claim 1, wherein the horizontal portion of the S/D contact is horizontally in contact with a dummy sheet, the dummy sheet being directly on top of the first S/D region of the first transistor.

6. The semiconductor structure of claim 5, wherein the horizontal portion of the S/D contact and the dummy sheet have a substantially same thickness and are substantially coplanar.

7. The semiconductor structure of claim 1, wherein the first transistor is a first nanosheet transistor having a first set of nanosheets of a first width, the second transistor is a second nanosheet transistor having a second set of nanosheets of a second width, and the second width is narrower than the first width.

8. A method of forming a semiconductor structure comprising:
forming a first source/drain (S/D) region of a first transistor on a substrate;
forming a sacrificial sheet directly on top of the first S/D region of the first transistor;
forming a second S/D region of a second transistor, the second S/D region being on top of the first S/D region such that a portion of the first S/D region of the first transistor being vertically outside the second S/D region of the second transistor;
depositing a dielectric layer covering the first and the second S/D region;
creating a vertical opening in the dielectric layer, the vertical opening exposing the portion of the first S/D region;
selectively removing at least a portion of the sacrificial sheet to create a horizontal opening directly above the first S/D region of the first transistor; and
forming a S/D contact, the S/D contact having a horizontal portion in the horizontal opening and a vertical portion in the vertical opening.

9. The method of claim 8, wherein the vertical opening extends through the sacrificial sheet to expose a sidewall thereof.

10. The method of claim 9, wherein selectively removing the at least a portion of the sacrificial sheet comprises selectively etching the sacrificial sheet through the sidewall exposed by the vertical opening.

11. The method of claim 9, wherein selectively removing the at least a portion of the sacrificial sheet comprises selectively etching the sacrificial sheet to create the horizontal opening where at least a portion of the horizontal opening is vertically between the first S/D region of the first transistor and the second S/D region of the second transistor.

12. The method of claim 11, wherein selectively etching the sacrificial sheet causes a portion of the sacrificial sheet to remain above the first S/D region of the first transistor as a dummy sheet.

13. The method of claim 11, wherein selectively etching the sacrificial sheet causes the sacrificial sheet above the first S/D region of the first transistor being entirely removed.

14. The method of claim 8, wherein forming the S/D contact comprises depositing a conductive material in the horizontal opening and the vertical portion to form the horizontal portion and the vertical portion of the S/D contact.

15. A semiconductor structure comprising:
a first nanosheet transistor on a substrate;
a second nanosheet transistor on top of the first nanosheet transistor; and
a source/drain (S/D) contact contacting a first S/D region of the first nanosheet transistor,
wherein the S/D contact has a horizontal portion and a vertical portion, the horizontal portion extending from a sidewall of the vertical portion and covering a top surface of the first S/D region of the first nanosheet transistor.

16. The semiconductor structure of claim 15, wherein the first nanosheet transistor has a first set of nanosheets of a first width and the second nanosheet transistor has a second set of nanosheets of a second width with the second width being narrower than the first width, and wherein and a portion of the first S/D region of the first nanosheet transistor is vertically outside the second S/D region of the second nanosheet transistor.

17. The semiconductor structure of claim 16, wherein a bottom surface of the vertical portion of the S/D contact is in direct contact with the portion of the first S/D region of the first nanosheet transistor and is below the horizontal portion of the S/D contact.

18. The semiconductor structure of claim 16, wherein a portion of the sidewall of the vertical portion of the S/D contact is in direct contact with the portion of the first S/D region of the first nanosheet transistor and is below the horizontal portion of the S/D contact.

19. The semiconductor structure of claim 15, wherein at least a portion of the horizontal portion of the S/D contact is vertically between the first S/D region of the first nanosheet transistor and the second S/D region of the second nanosheet transistor, and the horizontal portion of the S/D contact is horizontally in contact with a dummy sheet, the dummy sheet being directly on top of the first S/D region of the first nanosheet transistor.

20. The semiconductor structure of claim 19, wherein the horizontal portion of the S/D contact and the dummy sheet have a substantially same thickness and are substantially coplanar.
